(19) United States
(12) Patent Application Publication
(10) Pub. No.: US 2007/0266287 A1
(43) Pub. Date: Nov. 15, 2007

(54) Spatial frequency response measurement method

(75) Inventor: Lenfu Liu, Jubei City (TW)

Correspondence Address: BIRCH STEWART KOLASCH & BIRCH, PO BOX 747, FALLS CHURCH, VA, 22040-0747, US

(73) Assignee: UMA Technology Inc.

(21) Appl. No.: 11/431,556

(22) Filed: May 11, 2006

(51) Int. Cl. G01R 31/28

(52) U.S. Cl. 714/738

(57) ABSTRACT

A spatial frequency response (SFE) measurement method applied for measuring an SFR of a specific area of an image module is disclosed. The method includes: utilizing the image module to obtain an image of a test pattern, wherein the test pattern includes a plurality of test areas, each test area includes a plurality of area pattern, each area pattern includes a plurality of slanted edges; calculating SFRs of area patterns corresponding to the specific area; and averaging the SFRs to obtain an averaged SFR as an MTF distribution of the specific area of the image module.

### BACKGROUND OF THE INVENTION

1. Field of the Invention

The present invention relates to a spatial frequency response (SFR) measurement method, and more particularly, to a method of measuring the spatial frequency response of an image module.

2. Description of the Related Art

As is known, modulation transfer functions (MTF) have become a symbol for evaluating the optical properties of optical devices or optical systems. For example, by detecting the response of MTF in all spatial frequencies corresponding to a specific area of a lens (the spatial frequency response, SFR), the resolution in all spatial frequencies (line densities) of the specific area of the lens can be determined.

Please refer to FIG. 1, which illustrates the process of performing SFR measurement by using a test pattern 100 according to the prior art. As shown in FIG. 1, the test pattern 100 has an edge, and the process of performing SFR measurement comprises following steps: First, utilizing the image module under test (for example, it can be the above-mentioned lens) to obtain an image of the test pattern 100; then a system analyzes the image to obtain the luminance distribution of the image (the edge spread function shown in FIG. 1), then a partial differential calculation is performed on the edge spread function shown in FIG. 1 to transform the edge spread function into a line spread function; at last, a fast fourier transform (FFT) is performed on the line spread function to generate aforementioned SFR (the figure having the relationship between the MTF and spatial frequency shown in FIG. 1).

Unfortunately, the test pattern 100 shown in FIG. 1 introduces some disadvantages. For example, when the image is being analyzed, since the obtained pixels corresponding to the edge may not be obtained effectively, the sampling points, which should be utilized to form a boundary function, are not enough. Therefore, after the following calculation, the calculated SFR may be different from the actual performance of the image module under test.

Please refer to FIG. 2, which is a diagram illustrating another test pattern 200 and related process of performing SFR measurement according to the prior art. As shown in FIG. 2, in order to solve the above-mentioned problems, in ISO12233, the edge in the test pattern 200 is slanted (in other words, the angle of the edge is about 5 degree). This makes different lines of the image have different luminance distributions (because the pixels in different lines have different phases). As shown in FIG. 2, in ISO12233, the luminance distributions corresponding to different lines are combined to a composite line spread function through a proper combination. And then, as mentioned previously, a FFT is performed on the composite line spread function such that the SFR can be obtained. Please note that, more detailed operations can be referred to the content of ISO12233, and further illustration is thus omitted here.

It is noted that, since in ISO12233, the luminance distributions corresponding to four lines are combined to a composite line spread function, this equivalently increases sampling points of the edge such that a more correct SFR can be obtained. However, the above-mentioned modification in ISO12233 can increase only a few sampling points. In other words, if the noise is serious or a more persuasive SFR should be obtained, the modification cannot still meet the demands.

### SUMMARY OF THE INVENTION

In view of the above-mentioned problems, an object of the invention is to provide a SFR measurement method in order to solve the above-mentioned problems.

According to an embodiment of the present invention, a spatial frequency response (SFR) measurement method applied for measuring an SFR of a specific area of an image module under test is disclosed. The SFR measurement method comprises: utilizing the image module under test to obtain an image of a test pattern, wherein the test pattern comprises a plurality of test areas, each test area comprises a plurality of area patterns, each area pattern has a plurality of slanted edges; analyzing the image to find out luminance distributions of the slanted edges of area patterns of at least one test area corresponding to the specific area; respectively performing a partial differential operation on each luminance distribution of the slanted edges of the area patterns of the test area corresponding to the specific area to transform each luminance distribution into a line spread function; respectively performing a fourier transform on each line spread function of each area pattern to generate an SFR corresponding to each area pattern; and averaging SFRs of area patterns to obtain an averaged SFR, and taking the averaged SFR as an modulation transfer function (MTF) distribution of the specific area of the image module.

The present invention test pattern can efficiently increase the number of edges such that the sampling points are enormously increased. In addition, the present invention utilizes an average. That is, the present invention averages SFR corresponding to each edge. Because the sampling points are increased and obtained SFRs are averaged, the affects caused by the noises are not apparent. In other words, the present invention SFR measurement method can enormously reduces the interferences of noises and obtains a more stable MTF distribution (SFR).

### BRIEF DESCRIPTION OF THE DRAWINGS

FIG. 1 illustrates the process of performing SFR measurement by using a test pattern according to the prior art.

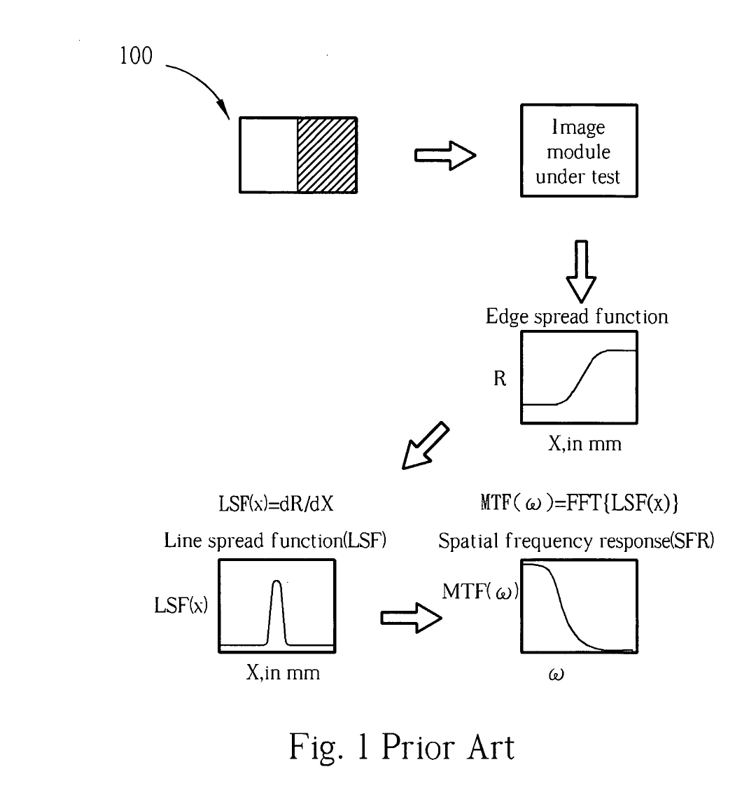

FIG. 2 is a diagram illustrating another test pattern and related process of performing SFR measurement according to the prior art.

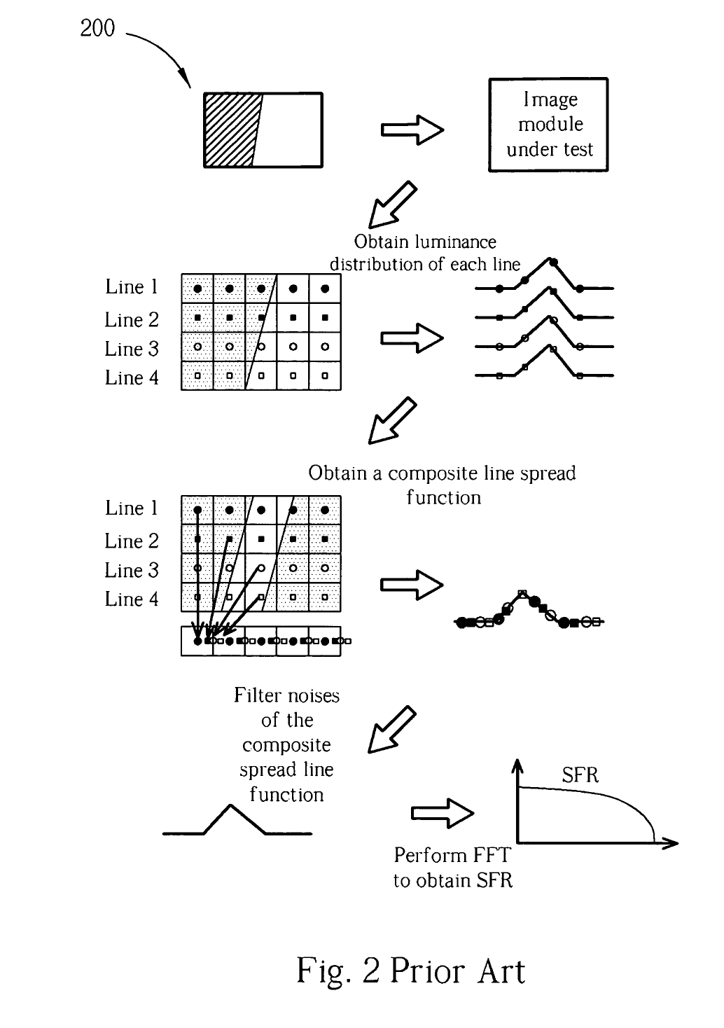

FIG. 3 is a diagram of a first embodiment of a test pattern according to the present invention.

FIG. 4 is a flow chart showing the test pattern shown in FIG. 3 and related process of performing SFR measurement according to the present invention.

FIG. 5 is a diagram of a second embodiment of a test pattern according to the present invention.

FIG. 6 is a diagram of a third embodiment of a test pattern according to the present invention.

### DETAILED DESCRIPTION OF THE INVENTION

The “TITLE” of the invention will be described with reference to the accompanying drawings.

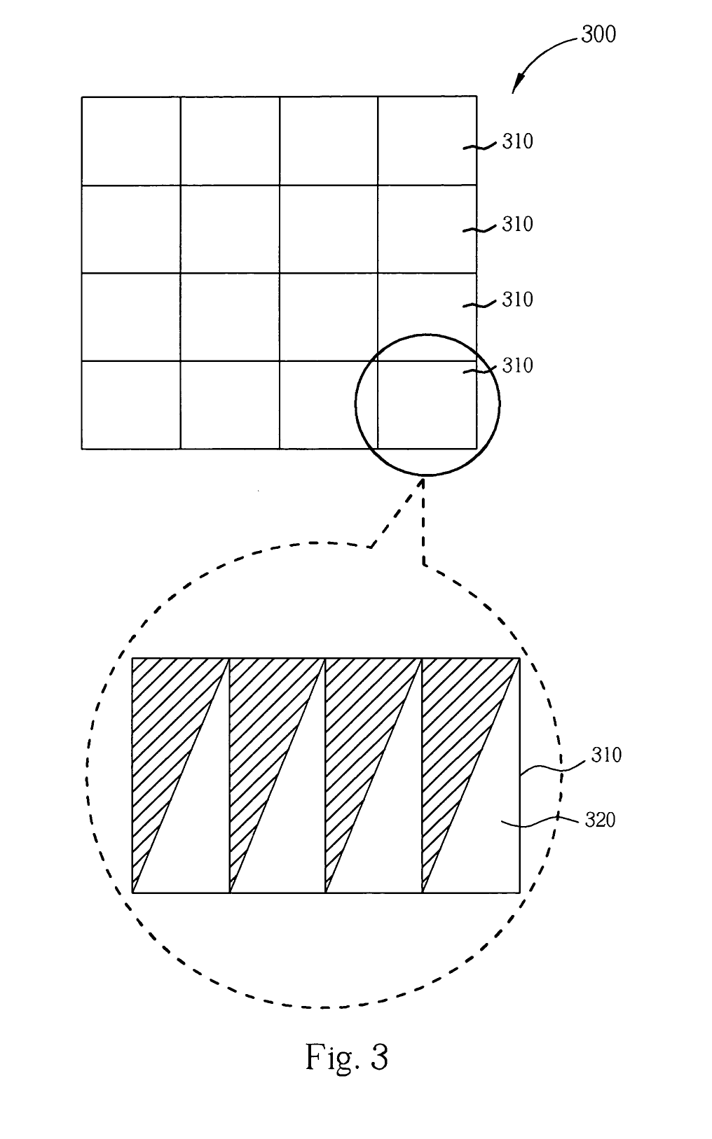

Please refer to FIG. 3, which is a diagram of a first embodiment of a test pattern 300 according to the present invention. As shown in FIG. 3, the test pattern 300 comprises a plurality of test areas 310. Moreover, each test area 310, shown as the scale-up figure in FIG. 3, is composed of a plurality of area patterns 320. As shown in FIG. 3, each area patterns 320, which is the same as the above-mentioned test pattern 200, has a slanted edge having a angle of 5 degree.

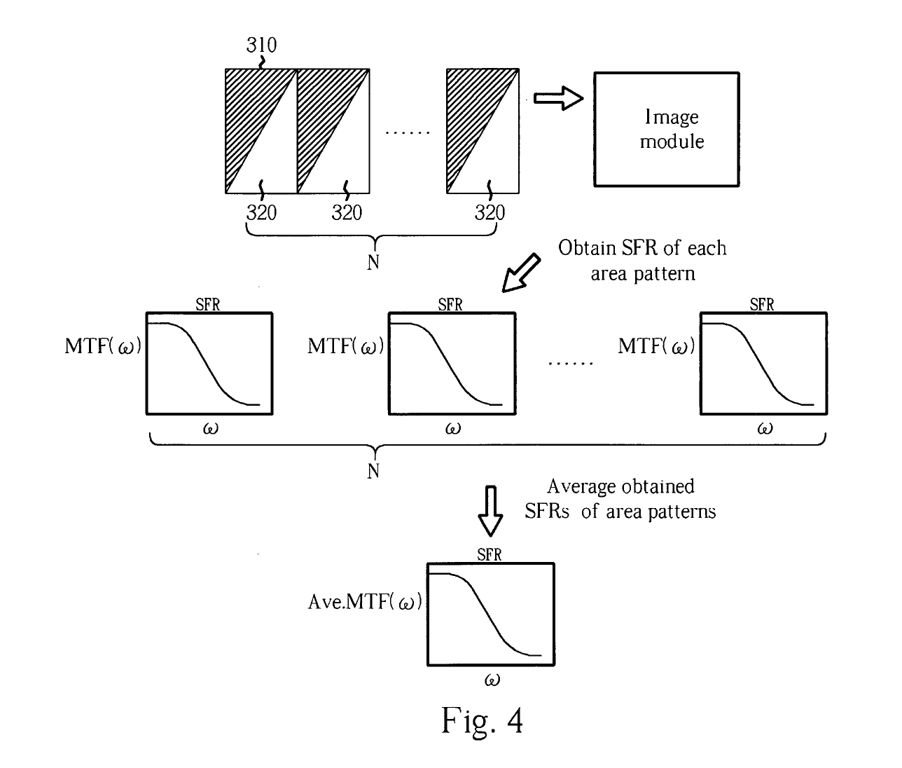

Please refer to FIG. 4, which is a flow chart illustrating related process of performing SFR measurement using the test pattern 300 shown in FIG. 3. Please note that, the present invention SFR measurement method of the test pattern 300 is similar to that of the test pattern 200. The difference between them is: each test area 310 of the test pattern 300 comprises a plurality of area patterns 320 (that is, N area patterns 320 shown in FIG. 4), and each area pattern 320 has an edge, and the area patterns 320 are arranged in one dimension.

As shown in FIG. 4, for the edge of each area pattern 320 in the test pattern, the above-mentioned SFR measurement method disclosed in ISO12233 can be performed on each area pattern 320 to obtain a corresponding SFR. (as mentioned previously, the ISO12233 SFR measurement method includes: utilizing the image module to obtain an image of the area pattern 320; analyzing the obtained image to find out the luminance distribution of the edge of the area pattern 320; performing a partial differential operation on the luminance distribution of the edge of the area pattern 320 to transform it into a line spread function; performing an FFT on the line spread function of the area pattern 320 to generate an SFR of the area pattern) Therefore, N SFRs corresponding to N area patterns 320 can be obtained. Please note that, the present invention averages the obtained N SFRs to generate an averaged SFR, and takes the averaged SFR as the MTF distribution (SFR) of the image module.

For example, if an SFR corresponding to a center area of the image module should be obtained, the above-mentioned steps can be utilized. That is, the center area of the image corresponding to the test pattern 300 can be utilized. And then, a plurality of SFRs corresponding to edges of all area patterns 320 corresponding to the center area are obtained. And these obtained SFRs are averaged such that the MTF distribution corresponding to the center area of the image module is obtained.

Since the test pattern 300 comprises a plurality of area patterns 320 (comprises many slanted edges), the sampling points are equivalently increased. And the present invention utilizes the averaging operation to average a plurality of SFRs of a plurality of area patterns 320. Therefore, the influences caused by noises upon the SFR are not apparent. In other words, the present invention SFR measurement method can prevent from noise interferences, and can get a more stable MTF distribution.

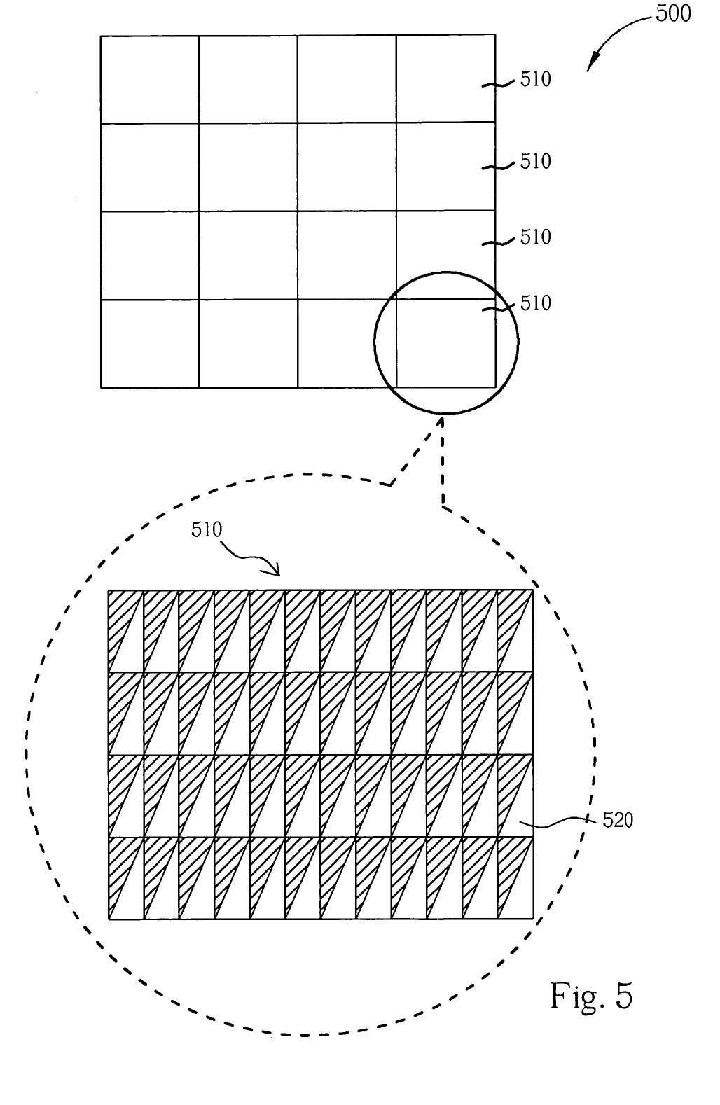

Please refer to FIG. 5, which is a diagram of a second embodiment of a test pattern 500 according to the present invention. As shown in FIG. 5, the test pattern 500 also comprises a plurality of test areas 510. Each teat area 510 is composed of area patterns 520. Please note that, the area pattern 520 are similar to the area pattern 320 shown in FIG. 3. They both have a slanted edge having 5 degree angle. The difference between them is: the area patterns 520 are arranged in the test area 510 in two dimension.

Moreover, the process of performing the SFR measurement is also similar. That is, a plurality of SFRs corresponding to the area patterns 520 are obtained. And then, the SFRs are averaged to obtain the MTF distribution of the image module. Those skilled in the art should know related operations, and further illustration is thus omitted here.

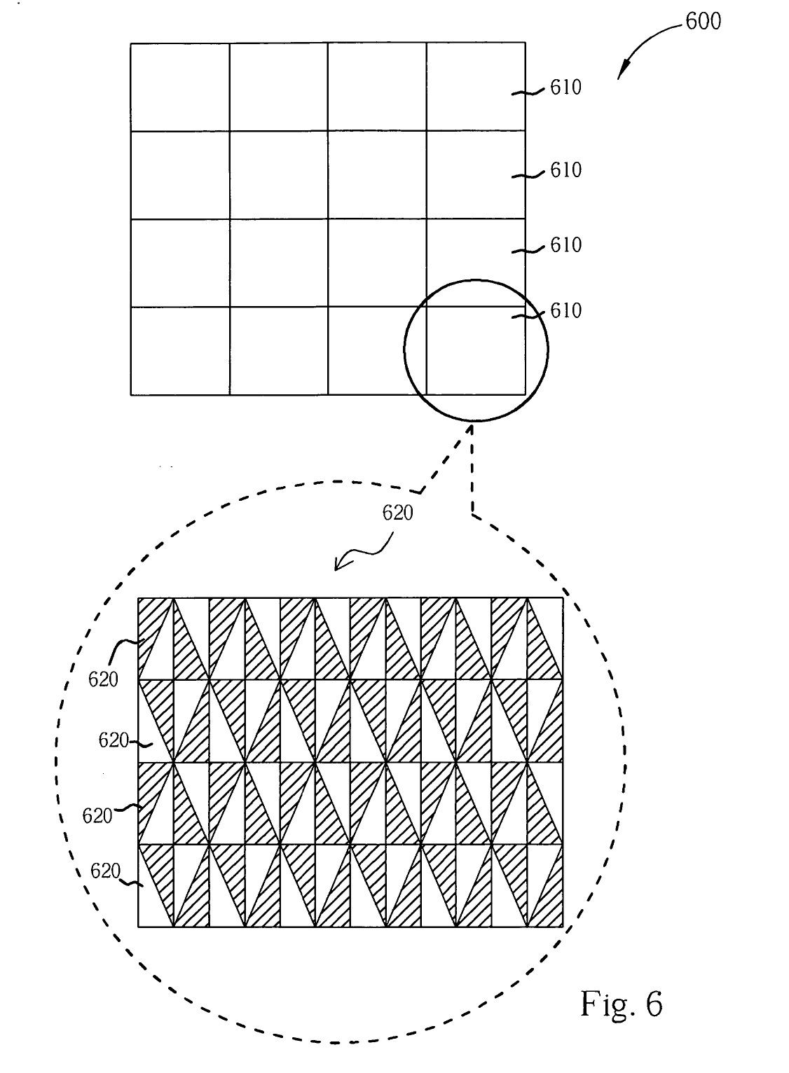

Please refer to FIG. 6, which is a diagram of a third embodiment of a test pattern 600 according to the present invention. As shown in FIG. 6, the test pattern 600 also comprises a plurality of test areas 610, and each test area 610 comprises a plurality of area patterns 620.

Please note that, the area pattern 620 is similar to the area pattern 520 shown in FIG. 5. They both have an edge of an angle. The difference between them is: the area pattern 620 varies. As shown in FIG. 6, two adjacent area patterns 620 are symmetric. This is used for increasing the variances of sampling such that the noise interferences can be further reduced.

Furthermore, the SFR measurement corresponding to the test pattern 600 is similar to that corresponding to the test pattern 500. That is, a plurality of SFRs corresponding to a plurality of area patterns 620 are obtained.(that is, the MTF distribution of the edge each area pattern 620 is obtained) And then the SFRs are averaged such that the MTF distribution of the image module can be obtained. Those skilled in the art can understand related operations, and further illustration is omitted here.

It is noted that, in the above-mentioned disclosure, each area pattern in the test pattern is the same. But this is only utilized as an embodiment, not a limitation of the present invention. For example, different test areas in the test pattern can have area patterns in different spatial frequencies. In addition, the above-mentioned test patterns are all utilized to detect the MTF distribution in horizontal. Therefore, in the test pattern, the aforementioned test areas can be rotated 90 degree to support MTF distribution measurement in vertical. This change also obeys the spirit of the present invention.

Furthermore, the present invention test pattern and related SFR measurement method can be applied for all optical devices and image modules. In other words, the present invention is not limited to be applied to a specific image module.

In contrast to the prior art, the present invention test pattern can efficiently increase the number of edges such that the sampling points are enormously increased. In addition, the present invention utilizes an average. That is, the present invention averages SFR corresponding to each edge. Because the sampling points are increased and obtained SFRs are averaged, the affects caused by the noises are not apparent. In other words, the present invention SFR measurement method can enormously reduces the interferences of noises and obtains a more stable MTF distribution (SFR).

While certain exemplary embodiments have been described and shown in the accompanying drawings, it is to be understood that such embodiments are merely illustrative of and not restrictive on the broad invention, and that this invention should not be limited to the specific construction and arrangement shown and described, since various other modifications may occur to those ordinarily skilled in the art.

What is claimed is:

1. A spatial frequency response (SFR) measurement method applied for measuring an SFR of a specific area of an image module under test, the SFR measurement method comprising:
utilizing the image module under test to obtain an image of a test pattern, wherein the test pattern comprises a plurality of test areas, each test area comprises a plurality of area patterns, each area pattern has a plurality of slanted edges;
analyzing the image to find out luminance distributions of the slanted edges of area patterns of at least one test area corresponding to the specific area;
respectively performing a partial differential operation on each luminance distribution of the slanted edges of the area patterns of the test area corresponding to the specific area to transform each luminance distribution into a line spread function;
respectively performing a fourier transform on each line spread function of each area pattern to generate an SFR corresponding to each area pattern; and
averaging SFRs of area patterns to obtain an averaged SFR, and taking the averaged SFR as an modulation transfer function (MTF) distribution of the specific area of the image module.

2. The SFR measurement method of claim 1, wherein in each test area, the plurality of area patterns are all the same.

3. The SFR measurement method of claim 1, wherein in each test area, two adjacent area patterns of the plurality of area patterns are symmetric.

4. The SFR measurement method of claim 1, wherein in each test area, the plurality of area patterns are arranged in one dimension.

5. The SFR measurement method of claim 1, wherein in each test area, the plurality of area patterns are arranged in two dimension.
